(19) United States
(12) Patent Application Publication
(10) Pub. No.: US 2013/0112267 A1
(43) Pub. Date: May 9, 2013

(54) Reinforcing Members For Photovoltaic Modules

(71) Applicant: Kevin Lee Wasson, Elmira, NY (US)

(72) Inventor: Kevin Lee Wasson, Elmira, NY (US)

(21) Appl. No.: 13/289,201

(22) Filed: Nov. 4, 2011

(51) Int. Cl. H01L 31/0203; H01L 31/18

(52) U.S. Cl. 136/259; 438/64; 257/E31.117

(57) ABSTRACT

A thin film photovoltaic module that is connectable to a terminal includes a first glass sheet defining a sun facing surface and a second glass sheet defining a back facing surface opposite the front side surface. The second glass sheet includes a feed-though opening extending through the second glass sheet. A photovoltaic material is between the first glass sheet and the second glass sheet. An encapsulant material is between the first glass sheet and the second glass sheet that bonds the first glass sheet and the second glass sheet together and seals the photovoltaic material from moisture. A conductor is electrically connected to the photovoltaic material at one end. The conductor passes through the feed-though opening. A reinforcing member is disposed on the sun facing surface of the first glass sheet. The reinforcing member has a footprint hanging over at least a portion of the feed-through opening.

### FIELD

The present specification generally relates to photovoltaic modules, and more particularly to photovoltaic modules that include reinforcing members for reducing stresses in the photovoltaic modules.

### BACKGROUND

Photovoltaic modules often use light energy (photons) from the sun to generate electricity through a photovoltaic effect. A thin film photovoltaic module typically consists of two pieces of glass that are laminated together using a thin sheet of polymeric material. One of the glass members has photovoltaic materials deposited onto its surface. Photovoltaic modules should be constructed to endure various environmental conditions that cause stresses in the glass members. Accordingly, reinforcing structures are needed for reducing stresses in the glass members.

### SUMMARY

In one embodiment, a thin film photovoltaic module that is connectable to a terminal includes a first glass sheet defining a sun facing surface and a second glass sheet defining a back facing surface opposite the front side surface. The second glass sheet includes a feed-though opening extending through the second glass sheet. A photovoltaic material is between the first glass sheet and the second glass sheet. An encapsulant material is between the first glass sheet and the second glass sheet that bonds the first glass sheet and the second glass sheet together and seals the photovoltaic material from moisture. A conductor is electrically connected to the photovoltaic material at one end. The conductor passes through the feed-though opening. A reinforcing member is disposed on the sun facing surface of the first glass sheet. The reinforcing member has a footprint hanging over at least a portion of the feed-through opening.

In another embodiment, a thin film photovoltaic module that is connectable to a terminal includes a first glass sheet defining a sun facing surface and a second glass sheet defining a back facing surface opposite the front side surface. The second glass sheet includes a feed-though opening extending through the second glass sheet. A photovoltaic material is between the first glass sheet and the second glass sheet. An encapsulant material is between the first glass sheet and the second glass sheet that bonds the first glass sheet and the second glass sheet together and seals the photovoltaic material from moisture. The feed-through opening defining an unbonded region between the first glass sheet and the second glass sheet. A conductor is electrically connected to the photovoltaic material at one end. The conductor passes through the feed-though opening. A reinforcing member is disposed on the sun facing surface and extends into the unbonded region of the first glass sheet.

In another embodiment, a method of reducing bending stresses in a thin film photovoltaic module comprising a first glass sheet defining a sun facing surface, a second glass sheet defining a back facing surface opposite the front side surface and a photovoltaic material between the first glass sheet and the second glass sheet is provided. The method includes providing the second glass sheet with a feed-though opening extending through the second glass sheet through which a conductor passes. The first glass sheet and the second glass sheet are bonded together with an encapsulant material between the first glass sheet and the second glass sheet thereby sealing the photovoltaic material from moisture. A reinforcing member is disposed on the sun facing surface of the first glass sheet such that the reinforcing member has a footprint hanging over at least a portion of the feed-through opening.

Additional features and advantages of the claimed subject matter will be set forth in the detailed description which follows, and in part, will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 is a side section view of an embodiment of a photovoltaic module;

FIG. 2 is a quarter section perspective view of the photovoltaic module of FIG. 1;

FIG. 3 is a quarter section perspective view of the photovoltaic module of FIG. 1;

FIG. 4 is a quarter section perspective view of the photovoltaic module of FIG. 1 with an embodiment of a reinforcing member; and

FIG. 5 illustrates an exemplary reinforcing member footprint of the reinforcing member of FIG. 4 on a sun facing surface laid over an opening footprint of a feed-through opening on the sun facing surface.

### DETAILED DESCRIPTION

Embodiments described herein generally relate to thin film photovoltaic modules including reinforcing features that serve to reduce stresses that occur in glass sheets, for example, due to an impact. For example, International Electrotechnical Commission (IEC) document 61646, “Thin-Film Terrestrial Photovoltaic (PV) Modules—Design Qualification and Type Approval,” incorporated herein by reference, states that a thin film photovoltaic module must withstand impacts by one-inch diameter ice balls projected in a direction perpendicular to the photovoltaic module face at a speed of 23 m/s (51 mph). The reinforcing features help reduce the stresses in the glass sheets due to such an impact to prevent any breakage.

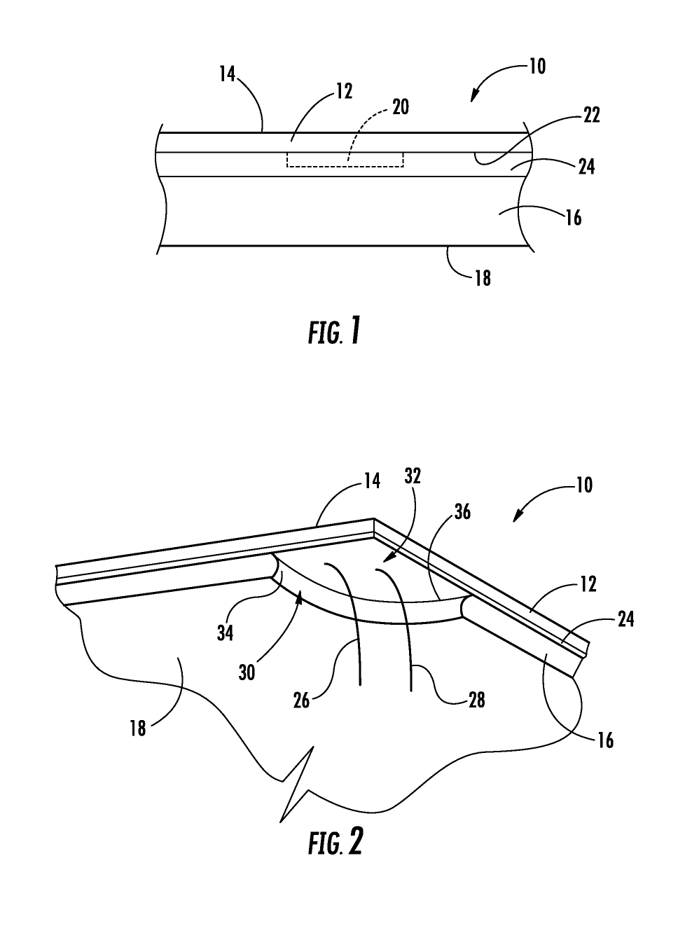

Referring to FIG. 1, a section view of a photovoltaic module 10 includes a relatively thin glass sheet 12 (e.g., less than about one mm, such as 0.7 mm) forming a sun facing surface 14. The glass sheet 12 may be a specialty glass commercially available from Corning Incorporated. The photovoltaic module 10 further includes a thicker glass sheet 16 (e.g., greater than one mm, such as 3.2 mm) forming a back facing surface 18 that faces opposite the sun facing surface 14. The glass sheet 16 may be a soda lime glass that may or may not be heat strengthened. In another embodiment, the glass sheet 16 may be replaced with a specialty glass also commercially available from Corning Incorporated, which may be thinner than 3.2 mm. For example, the glass sheet 12 and the glass sheet 16 may have about the same thicknesses. Photovoltaic materials (represented by element 20) are located between the glass sheet 12 and the glass sheet 16. In some embodiments, the photovoltaic materials are deposited on an internal side 22 of the glass sheet 12. A central polymeric layer 24, called the encapsulant or interlayer, may be provided between the glass sheets 12 and 16. The encapsulant layer 24 may serve two purposes: First, it can bond the two glass sheets 12 and 16 together into one structural member. Second, the encapsulant layer 24 can seal the photovoltaic materials 20 that are sandwiched between the two glass sheets 12 and 16 from moisture ingress over the expected life of the photovoltaic module 10, which can be 30 years or more.

The encapsulant material used for thin film photovoltaic modules 10 may be ethylene vinyl acetate (EVA) or polyvinyl butyral (PVB), as examples. These materials may be in solid sheet form with a thickness of approximately 0.4 mm to 0.76 mm. The three components (glass with PV/encapsulant/cover glass) may be stacked and placed into an autoclave oven during formation of the photovoltaic module 10. The assembly may be first heated to sufficient temperature to melt the encapsulant layer 24 and evacuated to remove air and moisture. A press force may be applied to the stacked assembly so that the melted encapsulant material fills void regions between the glass sheets 12 and 16. The encapsulant layer 24 solidifies as the assembly is cooled.

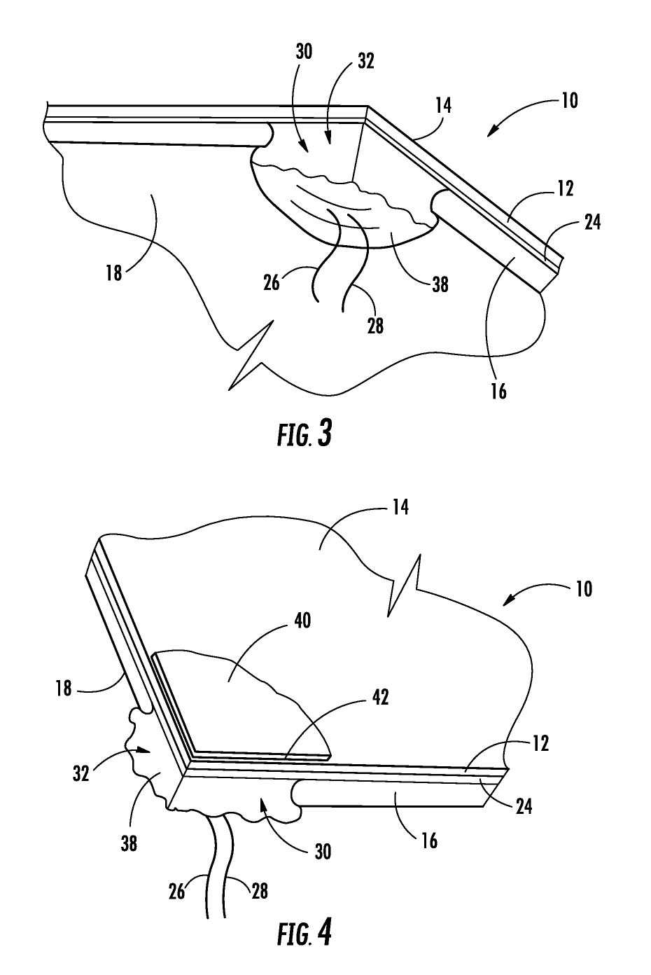

Referring to FIG. 2, a quarter section of the photovoltaic module 10 is shown and may include conductors 26 and 28 (e.g., wires) are in contact with the photovoltaic materials 20 and are used to carry the power generated by the photovoltaic materials 20 to devices that process the power into a useable form. A feed-through opening 30 may be provided in a centralized region of the glass sheet 16 (as opposed to an edge of the glass sheet 16) so that the conductors 26 and 28 may pass out of the photovoltaic module 10 (e.g., to be connected to a terminal). The feed-through opening 30 may be provided in the centralized region of the glass sheet 16 such that the relatively delicate conductors 26 and 28 can be protected with a junction box or other protective cover.

Providing a feed-through opening 30 through the glass sheet 16 provides an unbonded region 32 between the glass sheet 12 and the glass sheet 16. For example, for a radiused opening sidewall 34, the unbonded region 32 begins at an inner opening edge 36 where the glass sheet 16 is bonded to the glass sheet 12. Referring briefly to FIG. 3, a potting material 38 may be used to fill the feed through opening 30 through the glass sheet 16. The potting material 38 may have material properties selected to support and stiffen the glass sheet 12 in the unbonded region 32 defined by the feed-through opening 30 to improve the reliability of the photovoltaic module 10.

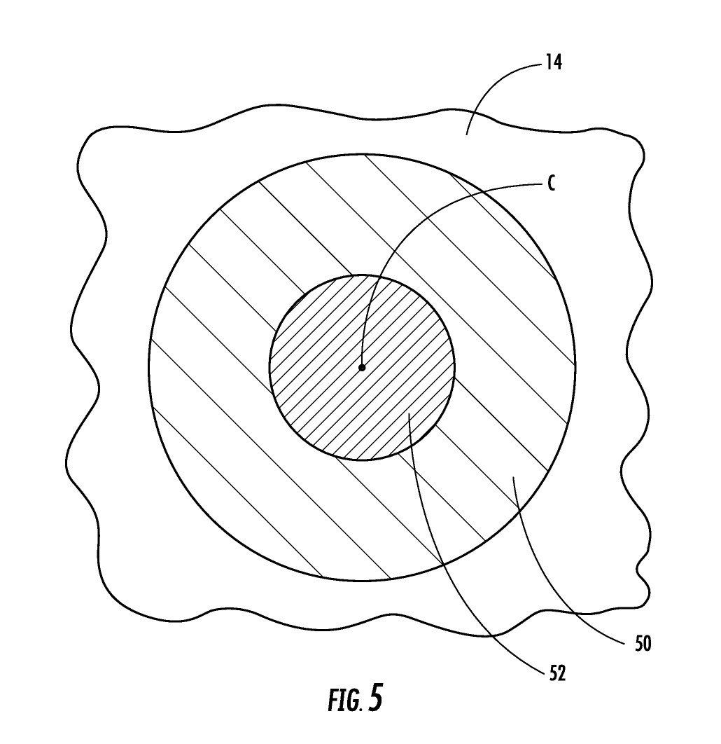

As can be appreciated, presence of the unbonded region 32 and absence of the glass sheet 16 in this unbonded region 32 can leave the glass sheet 12 providing the sun facing surface 14 vulnerable to stresses, particularly impact stresses since the glass sheet 12 may take the brunt of the impact and bending loads at the unbonded region 32. Referring now to FIG. 4, a reinforcing member 40 is disposed on the sun facing surface 14 of the glass sheet 12. The reinforcing member 40 covers at least a portion of the feed-through opening 30, extending into the unbonded region 32 between the glass sheet 12 and the glass sheet 16. The reinforcing member 40 may be a flat glass sheet material, for example, of specialty glass commercially available from Corning Incorporated. The thickness of both the glass sheet 12 and the reinforcing member 40 may be determined by economics and product reliability requirements. The thickness of the reinforcing member 40 may chosen to significantly increase the rigidity of the photovoltaic module 10 while keeping the reinforcing member thickness to a reasonably small value and therefore low cost and low profile height above the sun facing surface 14 of the glass sheet 12. The thickness of the glass sheet 12 and that of the reinforcing member 40 may be about the same, such as about 0.7 mm.

An adhesive layer 42 may be used to attach the reinforcing member 40 to the sun facing surface 14 of the glass sheet 12. The adhesive material of the adhesive layer 42 may have a small thickness as well as a modulus of elasticity large enough that there is a relatively low amount of shear deformation occurring within the cross-section of the adhesive layer 42. The large modulus of elasticity for the adhesive layer 42 may be selected such that the glass sheet 12 and the reinforcing member 42 act nearly as if they were one single piece of glass with a thickness equal to the sum of the glass sheet 12 and the reinforcing member 40 plus the thickness of the adhesive layer 42. Even if the adhesive material selected has a relatively low modulus of elasticity, the assembly can behave as if it were two pieces of glass allowed to slide relative to each other, and the reinforcing member 40 can still act to stiffen the assembly and reduce the bending that occurs in the glass sheet due to an impact force, thereby improving reliability.

FIG. 5 illustrates an exemplary reinforcing member footprint 50 of the reinforcing member 40 on the sun facing surface 14 laid over an opening footprint 52 of the feed-through opening 30 on the sun facing surface 14. The reinforcing member footprint 50 should significantly overlap the opening footprint 52 over the entire area of the opening footprint 52 in order to adequately limit bending distortion of the glass sheet 12 upon an impact force applied at a location corresponding to a center C of the feed-through opening 30. For example, the overlap distance may be at least 3 times the thickness of the reinforcing member 40. In some embodiments, the reinforcing member footprint 50 may have an area that is larger than an area of the opening footprint 52. In these embodiments, the reinforcing member footprint 50 may overlie the entire opening footprint 52.

When selecting the reinforcing member 40 and the adhesive layer 42, various attributes may be considered. The resulting modulus of elasticity (Young's modulus) of the adhesive material after the material has cured may be considered. A high modulus of elasticity (e.g., of at least about 3 MPa) may be desired. The thicknesses of the reinforcing member 40 and the adhesive layer 42 may be kept small in order to keep the height of the reinforcement member 40 as compact as possible. Higher profiles of the reinforcing member 40 are more likely to be impacted during module installation, for example. Higher profiles of the reinforcing member 40 also tend to more readily collect debris when the photovoltaic module 10 is in use, thereby blocking sun exposure and reducing module efficiency. The adhesive strength may be as high as possible. The optical transmittance of the adhesive layer 42 (and the reinforcing member 40) should be as high as possible (e.g., a hemispherical transmittance of at least about 85 percent over an optical wavelength range of 400 nanometers to 1100 nanometers) in order to minimize loss of sun energy exposing the PV material. The photovoltaic module 10 may be mounted outdoors and can experience a variety of environmental conditions, and the potting material must withstand these conditions and still serves its functions for the life of the photovoltaic module 10. The adhesive material may be selected to resist yellowing when exposed to UV light over long durations. As one example, the adhesive used to attach the reinforcing member 40 to the photovoltaic module 10 may be Dow Corning model PV-6100 which has excellent adhesive, durability, and energy transmission properties. The thickness of this adhesive layer 42 may be for example, 0.1 to 0.5 mm thick.

The above-described thin film photovoltaic (PV) modules 10 include a feed-through opening 30 that serves the purpose of allowing electrical conductors to pass from the photovoltaic material layer externally to a point outside the module, in which an additional reinforcing member 40 (e.g., formed of glass) that is significantly larger than the diameter of the feed-through opening 30 is attached with an adhesive to the sun facing surface 14 of the glass sheet 12. This reinforcing member 40 can serve to stiffen the sun side glass sheet 12 in the unbonded region of the feed-through opening, thereby reducing bending stresses that occur in the sun side glass when impacted with an ice ball (or hail) and subsequently improving the reliability of the module. The additional reinforcing member 40 and the adhesive layer 42 which is used to attach it to the glass sheet 12 both have optical transmitting properties such that a negligible reduction in sun power is delivered to the thin film PV materials. The tensile stress levels in the glass sheet 12 can be reduced by a factor of 10.

It will be apparent to those skilled in the art that various modifications and variations can be made to the embodiments described herein without departing from the spirit and scope of the claimed subject matter. Thus, it is intended that the specification cover the modifications and variations of the various embodiments described herein, provided such modification and variations come within the scope of the appended claims and their equivalents.

What is claimed is:

1. A thin film photovoltaic module that is connectable to a terminal, comprising:
a first glass sheet defining a sun facing surface;
a second glass sheet defining a back facing surface opposite the front side surface, the second glass sheet including a feed-though opening extending through the second glass sheet;
a photovoltaic material between the first glass sheet and the second glass sheet;
an encapsulant material between the first glass sheet and the second glass sheet that bonds the first glass sheet and the second glass sheet together and seals the photovoltaic material from moisture;
a conductor that is electrically connected to the photovoltaic material at one end, the conductor passing through the feed-though opening; and
a reinforcing member disposed on the sun facing surface of the first glass sheet, the reinforcing member having a footprint hanging over at least a portion of the feed-through opening.

2. The photovoltaic module of claim 1 further comprising an adhesive layer that bonds the reinforcing member to the sun facing surface of the first glass sheet.

3. The photovoltaic module of claim 2, wherein the adhesive layer is formed of a material having a modulus of elasticity of at least about 3 MPa.

4. The photovoltaic module of claim 2, wherein the adhesive layer has a thickness that is less than a thickness of the reinforcing member.

5. The photovoltaic module of claim 2, wherein the adhesive layer is between about 0.1 mm and about 0.5 mm thick.

6. The photovoltaic module of claim 2, wherein the adhesive layer has a hemispherical transmittance of at least about 85 percent over an optical wavelength range of 400 nanometers to 1100 nanometers.

7. The photovoltaic module of claim 1, wherein the reinforcing member is glass.

8. The photovoltaic module of claim 1, wherein the reinforcing member has a thickness of no more than about 1 mm.

9. The photovoltaic module of claim 1, wherein the footprint of the reinforcing member on the sun facing surface is greater in area than a footprint of the feed-through opening on the sun facing surface.

10. A thin film photovoltaic module that is connectable to a terminal, comprising:
a first glass sheet defining a sun facing surface;
a second glass sheet defining a back facing surface opposite the front side surface, the second glass sheet including a feed-though opening extending through the second glass sheet;
a photovoltaic material between the first glass sheet and the second glass sheet;
an encapsulant material between the first glass sheet and the second glass sheet that bonds the first glass sheet and the second glass sheet together and seals the photovoltaic material from moisture, the feed-through opening defining an unbonded region between the first glass sheet and the second glass sheet;
a conductor that is electrically connected to the photovoltaic material at one end, the conductor passing through the feed-though opening; and
a reinforcing member disposed on the sun facing surface extending into the unbonded region of the first glass sheet.

11. The photovoltaic module of claim 10, wherein the reinforcing member extends beyond the unbonded region of the first glass sheet.

12. The photovoltaic module of claim 10 further comprising an adhesive layer that bonds the reinforcing member to the sun facing surface of the first glass sheet.

13. The photovoltaic module of claim 12, wherein the adhesive layer is formed of a material having a modulus of elasticity of at least about 3 MPa.

14. The photovoltaic module of claim 12, wherein the adhesive layer has a thickness that is less than a thickness of the reinforcing member.

15. The photovoltaic module of claim 12, wherein the adhesive layer is between about 0.1 mm and about 0.5 mm thick.

16. The photovoltaic module of claim 12, wherein the adhesive layer has a hemispherical transmittance of at least about 85 percent over an optical wavelength range of 400 nanometers to 1100 nanometers.

17. The photovoltaic module of claim 10, wherein the reinforcing member is glass.

18. A method of reducing bending stresses in a thin film photovoltaic module comprising a first glass sheet defining a sun facing surface, a second glass sheet defining a back facing surface opposite the front side surface and a photovoltaic material between the first glass sheet and the second glass sheet, the method comprising:
providing the second glass sheet with a feed-though opening extending through the second glass sheet through which a conductor passes;
bonding the first glass sheet and the second glass sheet together with an encapsulant material between the first glass sheet and the second glass sheet thereby sealing the photovoltaic material from moisture; and
disposing a reinforcing member on the sun facing surface of the first glass sheet such that the reinforcing member having a footprint hanging over at least a portion of the feed-through opening.

19. The method of claim 18 further comprising bonding the reinforcing member to the first glass sheet using an adhesive layer the adhesive layer is formed of a material having a modulus of elasticity of at least about 3 MPa.

20. The method of claim 18, wherein the reinforcing member is glass having a thickness of no more than about 1 mm.
